(19) United States
(12) Patent Application Publication
(10) Pub. No.: US 2022/0139743 A1
(43) Pub. Date: May 5, 2022

(54) Optical Sensor for Inspecting Pattern Collapse Defects

(71) Applicant: Tokyo Electron Limited, Tokyo (JP)

(72) Inventors: Ivan MALEEV, Pleasanton, CA (US); Yan CHEN, Cupertino, CA (US); Ching-Ling MENG, Sunnyvale, CA (US); Xinkang TIAN, San Jose, CA (US)

(73) Assignee: Tokyo Electron Limited, Tokyo (JP)

(21) Appl. No.: 17/088,885

(22) Filed: Nov. 4, 2020

(51) Int. Cl. H01L 21/67; G01N 21/55; G01N 21/95; G01N 23/2251

(52) U.S. Cl. CPC H01L 21/67288; G01N 21/55; G01N 21/9505; G01N 23/2251; H01L 21/67034; G01N 2201/0635; H01L 21/67057; G01N 2223/07; G01N 2223/507; G01N 2223/418; H01L 21/67051

(57) ABSTRACT

An apparatus for detecting defects on a sample is provided. The apparatus includes a stage for receiving a sample to be inspected, and a first light source configured to generate an incident light beam to illuminate the sample on the stage. The first light source is configured to sequentially emit light of different wavelengths in wavelength sweeps. The apparatus also includes imaging optics for collecting light scattered from the sample and for forming a detection light beam, a detector for receiving the detection light beam and acquiring images of the sample, collection optics disposed within the detection light beam and configured to direct the detection light beam to the detector, and a first light modulator. The first light modulator is configured to filter out signals from the detection light beam, where the signals originate from uniform periodicity of uniformly repeating structures on the sample.

### CROSS REFERENCE TO RELATED APPLICATIONS

This application is related to U.S. patent application Ser. No. xx/xxx,xxx, entitled “Method and Apparatus for Inspecting Pattern Collapse Defects”, Attorney Docket No. 528099US, filed on Nov. 4, 2020, the entire contents of which is incorporated herein by reference.

### BACKGROUND

The present disclosure relates to an optical sensor for inspecting semiconductor structures for pattern collapse defects, and, more particularly, to methods, systems, and apparatuses for inspecting a semiconductor sample with a uniformly repeating structure to detect defects including deviations from uniform periodicity of the uniformly repeating structure.

Semiconductor wafer cleaning solutions are a critical part of the industry. The purpose of cleaning could be to remove residual by-products after other semiconductor process steps, such as etching or polishing. One may also desire to remove surface particles or unwanted films. A typical cleaning process can use one or multiple solvents such as SC1/SC2 liquids and an alcohol, such as isopropyl alcohol (isopropanol, IPA). At the end of the cleaning process it is also critical to remove from the wafer surface any traces of the cleaning solution itself. Established methods may use the agents that reduce surface tension and ability of cleaning solutions to “wet” the surface. Ideally one would like an agent with the surface tension approaching zero and the capability to turn into a gas without going through a phase transition. An example of the latter is supercritical carbon dioxide (scCO2).

In an exemplary embodiment of using the scCO2 to remove the traces of the cleaning solution, a wafer can be placed in a chamber where normally gaseous CO₂ turns into supercritical fluid state (scCO₂) at high pressure and temperature. scCO₂ can dissolve and displace a cleaning agent (e.g., isopropanol (IPA)) so that the chemicals can be removed via an exhaust port. At the end of the cleaning cycle only pure scCO2 remains. Then the pressure and the temperature in the chamber can be gradually reduced. Once below a supercritical point, CO₂ can turn into gas and leave the wafer dry and theoretically free from cleaning byproducts. However in practice a cleaning tool itself may introduce additional surface pattern defects and particles. Thus, a rapid after-cleaning inspection capability is desired. A post-wafer drying inspection step is desirable also in processes that involve more conventional drying methods, such as wafer spinning, allowing solvent to evaporate naturally or by forced convection, etc., all of which also may introduce surface pattern defects caused by capillary forces present during the drying step.

Traditional inspection methods can include a top-down CD-SEM inspection and a full-wafer optical inspection. However the CD-SEM inspection relies on direct imaging and has a limited field-of-view (FOV). For example, assuming 1000×1000 pixel FOV and 5 nm pixel size, the CD-SEM inspection can provide an image of only 5×5 um area. Scanning an area, such as a 1×1 mm area, can require 4E+10 pixels. Thus, the time and cost of inspecting a meaningful portion of a wafer quickly becomes prohibitive. On the opposite end of spectrum is the full-wafer optical inspection that can rapidly scan a wafer and rely on sensitivity techniques. However the cost of such universal systems is prohibitively high. There is an unmet need for a low-cost rapid review station that can detect after-cleaning defects in line with a cleaning tool operation.

The foregoing “Background” description is for the purpose of generally presenting the context of the disclosure. Work of the inventor, to the extent it is described in this background section, as well as aspects of the description which may not otherwise qualify as prior art at the time of filing, are neither expressly or impliedly admitted as prior art against the present invention.

### SUMMARY

A cleaning tool may generate surface particles due to impurities in cleaning agents and particulates in a cleaning chamber. Damage may include toppling defects on tops of pattern structures. However one key problem for the cleaning tool developers is the possibility of pattern collapse events in high aspect ratio structures due to surface tension forces of the cleaning agents. For example, in a three-dimensional structure neighboring pillars may stick together. Furthermore, initial collapse may trigger a chain of pattern collapse events. Multiple factors might be responsible. The factors may include incorrectly set up cleaning process, chamber design issues, and poor quality cleaning chemicals. In order to identify collapse events and control cleaning chamber operation, a feedback in the form of a low cost non-destructive review station is highly desired. The first goal for such station is to catch the event of catastrophic damage to a wafer. The second goal is to count individual defects and generate statistical data.

In the disclosure, embodiments are directed methods and apparatus (or review stations, or systems) for performing optical review of wafers after the wafers are processed on a cleaning tool. The apparatus are tailored for optical detection of pattern collapse events, but are also capable of detecting particles on a top surface of a patterned wafer, as well as other wafer defects. The methods are sensitivity based, where the signal from the periodic pattern can be minimized, so that the signal from the defects can be detectable. It is understood that the defects size is generally less than the Rayleigh limit of optical resolution.

There are two closely related types of defects that the review stations are designed to catch: individual “seed” pattern collapse events, and “chain” defects. In an example of a three-dimensional periodic structure of pillars, a “chain” defect starts with a seed defect, followed by collapse of a neighboring pillar, and then next one, and so on, eventually forming a zip line-like chain with two or more links. A key idea of the disclosure is that the effective pitch of a periodic structure with defects can alter from an original value. For example, if N structure pillars collapse in pairs and form a new structure of N/2 dual-pillars, the pitch of the new structure can increase by a factor of two. Angular and amplitude distribution of diffractive orders can change correspondingly. Therefore, a system (or a review station) that completely cancels out signal from an original structure, can register distorted signal from a structure with defects. The essence of the disclosure is that the review station can automatically minimize background signal from the original structure while maximize signal originating from described “chain” defects.

An aspect of the present disclosure includes a defect inspection apparatus (or apparatus) for detecting defects on a sample, where the sample can include a uniformly repeating structure, and the defects can include deviations from uniform periodicity of the uniformly repeating structure. The apparatus can include a stage (or a wafer stage) for receiving a sample to be inspected, and a light source configured to generate an incident light beam to illuminate the sample on the stage. The light source can sequentially emit light of different wavelengths in wavelength sweeps. The apparatus can also include imaging optics for collecting light scattered from the sample and for forming a detection light beam, a detector for receiving the detection light beam and acquiring images of the sample, collection optics disposed within the detection light beam and configured to direct the detection light beam to the detector, and a first light modulator. The first light modulator can be configured to filter out signals from the detection light beam, where the signals originate from the uniform periodicity of the uniformly repeating structures on the sample. Further, the defect inspection apparatus and detector are configured for imaging a region of a sample, where the region can have one dimension of at least 100 μm.

Another aspect of the present disclosure includes a defect inspection apparatus (or apparatus) for detecting defects on a sample. The sample can include a uniformly repeating structure, and the defects can include deviations from uniform periodicity of the uniformly repeating structure. The apparatus can include a stage for receiving a sample to be inspected, and a light source configured to generate an incident light beam to illuminate the sample on the stage. The light source can be configured to sequentially emit light of different wavelengths in wavelength sweeps. The apparatus can include imaging optics for collecting light scattered from the sample and for forming a detection light beam, a detector for receiving the detection light beam and acquiring images of the sample, collection optics disposed within the detection light beam and configured to direct the detection light beam to the detector, and a spatial light modulator (SLM) configured to filter out signals from the detection light beam. The signals can originate from the uniform periodicity of the uniformly repeating structures on the sample. The defect inspection apparatus and detector can be configured for imaging a region of a sample, where the region can have one dimension of at least 100 μm.

The foregoing paragraphs have been provided by way of general introduction, and are not intended to limit the scope of the following claims. The described embodiments, together with further advantages, will be best understood by reference to the following detailed description taken in conjunction with the accompanying drawings.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1 is a schematic diagram of an exemplary wafer cleaning system in accordance with some embodiments.

FIG. 2 is a schematic diagram of a first exemplary defect inspection apparatus in accordance with some embodiments.

FIG. 3 is a schematic diagram of a second exemplary defect inspection apparatus in accordance with some embodiments.

FIG. 4A is a schematic view of a first exemplary monochromator/wavelength filter in accordance with some embodiments.

FIG. 4B is a schematic view of a second exemplary monochromator/wavelength filter in accordance with some embodiments.

FIG. 4C is a schematic view of a third exemplary monochromator/wavelength filter in accordance with some embodiments.

FIG. 4D is a schematic view of a fourth exemplary monochromator/wavelength filter in accordance with some embodiments.

FIG. 4E is a schematic view of a fifth exemplary monochromator/wavelength filter in accordance with some embodiments.

FIG. 5A is a schematic diagram of an exemplary scattering hemisphere in accordance with some embodiments.

FIG. 5B is a schematic diagram of an exemplary pupil plane in accordance with some embodiments.

FIG. 6A is a first image of a periodic structure obtained by CD-SEM from a semiconductor sample in accordance with some embodiments.

FIG. 6B is a first pupil plane distribution after filtering out the periodic structure in accordance with some embodiments.

FIG. 7A is a second image of a periodic structure with multiple defects obtained by CD-SEM from a semiconductor sample in accordance with some embodiments.

FIG. 7B is a second pupil plane distribution after filtering out the periodic structure in accordance with some embodiments.

FIG. 8A is a 3D schematic view of a pupil plane filtering structure in accordance with some embodiments.

FIG. 8B is a top down view of the pupil plane filtering structure in accordance with some embodiments.

FIG. 8C is a front view of the pupil plane filtering structure in accordance with some embodiments.

FIG. 8D is a side view of the pupil plane filtering structure in accordance with some embodiments.

FIG. 9A is a schematic view of a scanning spectroscopic microscope in accordance with some embodiments.

FIG. 9B is a schematic view of sequential frame acquisition with multiple illumination modes based on the scanning spectroscope microscope in accordance with some embodiments.

### DETAILED DESCRIPTION

Reference throughout the specification to “one embodiment” or “an embodiment” means that a particular feature, structure, material, or characteristic described in connection with the embodiment is included in at least one embodiment, but do not denote that they are present in every embodiment. Thus, the appearances of the phrases “in one embodiment” in various places through the specification are not necessarily referring to the same embodiment. Furthermore, the particular features, structures, materials, or characteristics may be combined in any suitable manner in one or more embodiments.

In the disclosure, a system (or review station) is provided. The system can be a process-integrated optical review microscope with a tunable illumination light source or a tunable wavelength filter, and programmable pupil plane filtering of signals from periodic gratings. The disclosed system can collect separate digital images of a sample at multiple wavelengths of interest, and reconstruct spectroscopic information for each pixel.

Distinguishing features of the system (or review station) can include: (1) integration within a cleaning tool sequence of operations and ability to provide real-time feedback to the cleaning chamber; (2) wafer handling stage with precise focusing capability (e.g., <0.5 um) and ability to support point-by-point metrology measurements; (3) optical review microscope with sub-micrometer optical resolution and multi-wavelength illumination channels. The wavelengths of the system can be changed sequentially, allowing the optical review microscope to produce sequence of images, and create a rudimentary spectrum for each pixel; (4) the optical review microscope can use one or both of direct reflection (e.g., “bright field”) and scattering (e.g., “dark field”) measurement modes. Combination of direct reflection and the multi-wavelength illumination effectively offers the capability of a spectroscopic reflectometer with sub-micron pixel size in each pixel; (5) optical Fourier plane spatial light modulator/filter, placed in the pupil plane of the optical review microscope, and designed to cancel out signal from periodic structures or specified pitch.

A key advantage of the disclosed system, compared to a traditional spectroscopic solution, is the ability to extract spectroscopic information specific to a multitude of sub-micron sized areas, which allows the system to detect certain types of defects that normally cannot be detected by either microscopy or spectroscopic ellipsometry/reflectometry approaches.

The optical resolution, spatial distribution of optical rays, polarization, and wavelength/spectral properties are the key factors that affect sensitivity of an optical system. Typical microscopes provide high-resolution images of an object at one or few illumination wavelengths (WL). At the opposite end of capabilities are non-imaging spectroscopic scatterometers. Neither can provide detailed spectroscopic information about sub-micron area of interest on a wafer surface.

The process of formation of pattern collapse defects on e.g. two-dimensional shallow trench isolation (STI)-like structures may result in a zip line-like one-dimensional chain of links between individual pattern “pins”. Formation of a “zip” line implies an effective local change in pitch of a periodic structure. Spectroscopic measurements of diffraction gratings are extremely sensitive to the change in pitch. In fact, spectroscopic ellipsometry (SE) and reflectometry (SR) are preferred techniques for measuring properties of gratings (CD). However, locality of a pattern collapse defect implies that traditional large-spot SE/SR might have limited sensitivity due to the area with defects still being very small compared to spot size

In the disclosure, the large-spot SE/SR can be replaced with an imaging system (or a system, a review station), capable of performing spectroscopic analysis on a sub-micron-size pixel. Such a system can be built based on a regular microscope by adding a tunable light source, and named as a spectroscopic microscope.

In the disclosure, an optical architecture of the system can be formed based on an imaging microscope with an optical resolution below one um level and with a multi-pixel linear or area digital sensor. Assuming a sufficiently high numerical aperture (NA), appropriate design, and high quality of components, the imaging optical architecture can provide optical resolution performance intrinsically superior to any spot-scanning or otherwise non-imaging optical systems at a same wavelength. In the disclosure, a key feature includes an illumination subsystem that is based around a tunable light source, where the tunable light source can rapidly scan in time over a set of wavelengths of interest and provide spectroscopic information for each sub-micron pixel. Alternatively, tunable wavelength filter may be placed in an intermediate pupil plane of a collection subsystem of the system.

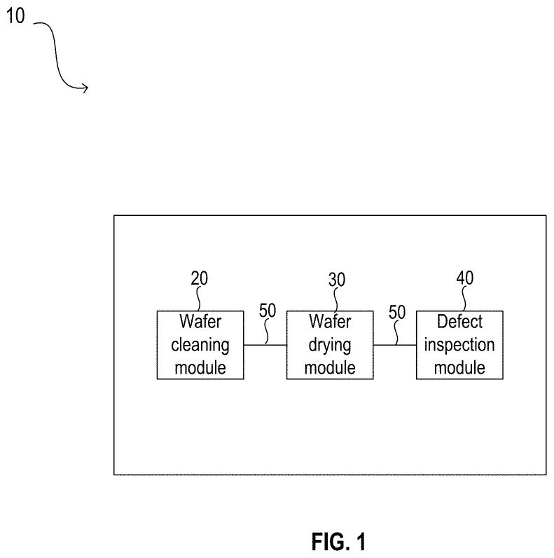

FIG. 1 is a schematic diagram of a wafer cleaning system 10 that can include a wafer cleaning module 20, a wafer drying module 30, a defect inspection module 40, and a wafer transfer module 50. The defect inspection module 40 is configured to inspect a wafer (not shown) that is received from the wafer drying module 30. The wafer transfer module 50 is configured to transfer the wafer between the wafer cleaning module 20, the wafer drying module 30, and the defect inspection module 40.

The wafer cleaning module 20 can be a single wafer cleaning platform or a bath/tank cleaning platform. In the single wafer cleaning platform, an etching chemistry (e.g., HF acid) or a cleaning chemistry (e.g., SC1) can be dispensed to a wafer that is positioned on the single wafer cleaning platform to performing a wet etching process or a wet cleaning process. In the bath/tank cleaning platform, the etching chemistry or the cleaning chemistry can be disposed in the bath/tank cleaning platform. A plurality of wafers can subsequently be soaked in the etching chemistry or the cleaning chemistry to receive a wet etching process or a wet cleaning process respectively. In some embodiments, an IPA can be applied in an etching or a cleaning step in the wafer cleaning module 20. For example, the wafer can be exposed to a liquid etchant and/or a cleaning liquid, and once the process is completed, deionized water, or preferably the IPA (for a low surface tension) can be sprayed onto the wafer to displace the etchant or cleaning liquid.

The wafer drying module 30 can also be a single wafer drying platform or a bath/tank drying platform. When the wafer drying module 30 is the single wafer drying platform, the wafer drying module 30 can apply a spin drying process to dry the wafer that is received from the wafer cleaning module 20. When the wafer drying module 30 is the bath/tank drying platform, a plurality of wafers can be dried together in the wafer drying module 30. In the wafer drying module 30, either scCO2 mentioned above can be used to dry the wafer, or other drying methods can be used to dry the wafer, such as a wafer spinning process, a gas blowing process that blows a gas (e.g., N2 gas) onto the wafer surface to promote evaporation, or a IPA dry process that applies an IPA vapor towards the wafer surface to cause a surface tension gradient which displaces the water on the wafer surface.

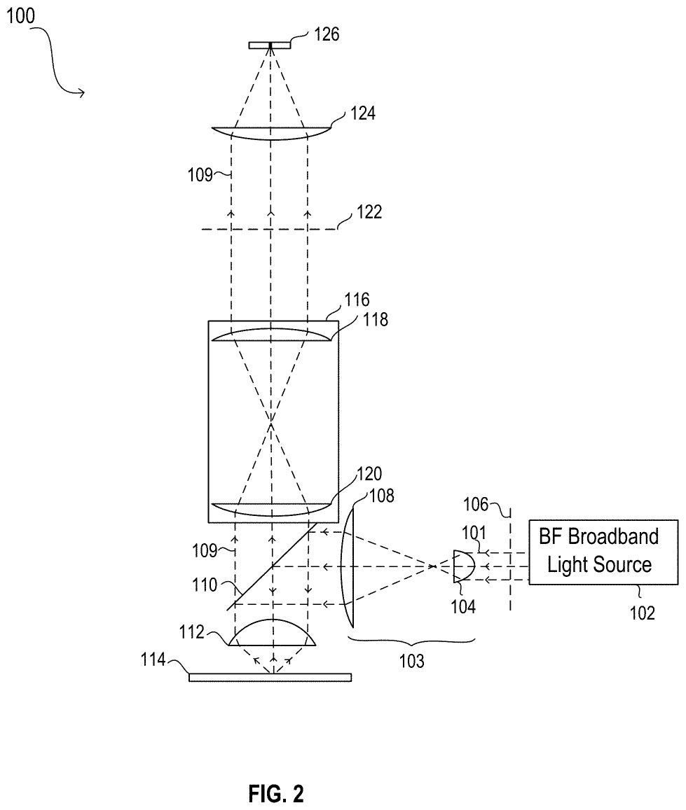

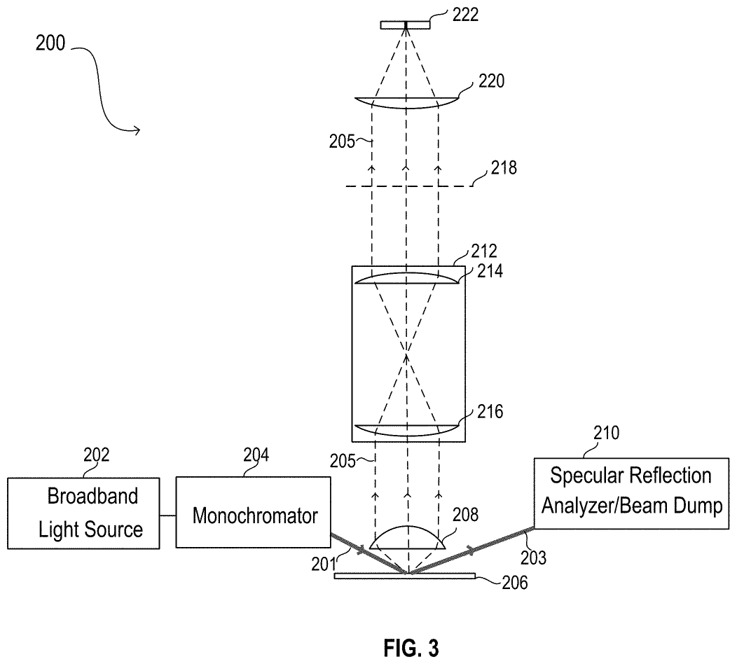

The defect inspection module 40 can include a defect inspection apparatus to catch surface defects that are positioned on the wafer surface. In some embodiments, the surface defects can be surface particles or surface contaminations from prior semiconductor manufacturing processes, such as a dry etching process, or a deposition process. In some embodiments, the surface defects can be caused by the wafer cleaning module 20 or the wafer drying module 30. For example, the surface defects can be toppling that is caused by the wafer drying module 30. An exemplary embodiment of the defect inspection apparatus can be illustrated in FIGS. 2-3.

FIG. 2 is schematic diagram of a first exemplary defect inspection apparatus (or a spectroscopic microscope, or a review station, or a system) 100 that provides bright filed illumination. As shown in FIG. 2, the spectroscopic microscope 100 can include a light source 102 with selectable illumination wavelength(s) in DUV-UV-VIS-IR range. The light source 102 can be either coherent or incoherent. The Light source 102 can be fiber-coupled or directly-coupled to either a bright field or a dark field illumination subsystem. In an exemplary embodiment of FIG. 2, the light source 102 is configured to provide bright field illumination. An incident light beam 101 can be generated by the light source 102 and directed to illumination pupil relay optics 103 that include a first lens 104 and a second lens 108. In some embodiments, the first lens 104 and the second lens 108 can be convex lenses. The illumination pupil relay optics 103 can be disposed within the incident light beam 101 and configured to form an illumination pupil plane 106 in cooperation with the light source 102. The incident light beam 101 can further be directed to a beam splitter 110 that is configured to direct the incident light beam 101 at a substantially vertical (i.e., 0 degree) or up to 5 degree angle of incidence upon a sample 114 that is positioned over a stage (not shown). In some embodiments, the sample 114 can be a portion of a wafer that includes a uniformly repeating structure. The incident light beam 101 can be reflected or scattered from the sample 114, and further be collected by imaging optics 112 for forming a detection light beam 109. The imaging optics 112 can be arranged over the sample 114 and positioned between the sample 114 and the beam splitter 110.

Still referring to FIG. 2, the detection light beam 109 can be directed to detection pupil relay optics 116. The detection pupil relay optics 116 can be disposed within the detection light beam 109 include a third lens 118 and a fourth lens 120. The detection pupil relay optics 116 can further direct the detection light beam 109 toward collection optics 124. The detection pupil relay optics 116 can be configured to form a detection pupil plane 122 in cooperation with the collection optics 124. The collection optics 124 can be disposed within the detection light beam 109, and configured to direct the detection light beam 109 to a detector (or sensor) 126. The detector 126 is configured to receive the detection light beam 109 and acquire images of the sample 114. In the preferred embodiment the sensor 126 is a multipixel two-dimensional (2D) area imaging sensor, such as Charged-Coupled Device (CCD) or Complementary Metal-Oxide-Semiconductor (CMOS) area sensor, multi-channel photomultiplier tube (PMT), or an array of photodiodes (PPD) or avalanche photodiodes (APD.) In some embodiments, the sensor 126 can be a Time-Delay Integration (TDI) 2D or multi-pixel one-dimension line (1D) sensor. The sensor 126 can also be a single-pixel sensor, such as a photomultiplier tube (PMT), a photodiode, or a photo detector. The sample 114 can be a semiconductor sample that includes a uniformly repeating structure and defects, where the defects include deviations from uniform periodicity of the uniformly repeating structure.

In some embodiments, a first light modulator (not shown) can be substantially positioned in the detection pupil plane 122. The first light modulator is configured to filter out signals from the detection light beam 109, where the signals originate from the uniform periodicity of the uniformly repeating structures on the sample 114. In some embodiments, the first light modulator can include at least one of a monochromator, a polarizer, a filter, a mask, a mechanical spatial light modulator (SLM) including multiple adjustable wires, a multi-pixel liquid crystal panel with controlled transmission, a MEMS structure with controlled transmission, or a controlled acousto-optical deflection structure. The first light modulator can maximize a signal-to-noise ratio, where optical photons originating from a periodic structure of specified dimensions & pitch can be considered to be noise, and optical photons originating from defects can be considered signal proper.

In some embodiments, a second light modulator (not shown) can be located substantially in the illumination pupil plane 106, wherein the second light modulator can include at least one of a monochromator, a polarizer, a filter, or a mask.

In some embodiments, the spectroscopic microscope 100 can be configured for imaging a region of the sample 114, where the region can have one dimension of at least 100 μm.

FIG. 3 is a schematic diagram of a second exemplary defect inspection apparatus (or spectroscopic microscope, or a system, or a review station) 200 that provides dark field illumination. As shown in FIG. 3, the spectroscopic microscope 200 can have a light source 202 that can be fiber-coupled or directly-coupled to a dark field illumination subsystem. The light source 202 can be further coupled to a monochromator 204 that is positioned between the light source 202 and a sample 206, and configured to adjust wavelengths of an incident light beam 201 generated by the light source 202. The incident light beam 201 can be directed to the sample 206 at an incidence angle of between 5 degree and 90 degrees. The incident light beam 201 can be reflected or scattered from the sample 206 and further be collected by imaging optics 208 for forming a detection light beam 205. The imaging optics 208 can be arranged over the sample 206 and positioned between the sample 206 and detection pupil relay optics 212. In some embodiments, the spectroscopic microscope 200 can further include a specular reflection analyzer 210 for detecting specularly reflected light 203 from the sample 206. In some embodiments, the specular reflection analyzer 210 can be a single-pixel or a multi-pixel (e.g., line, or time delay integration, or area) sensor.

The detection light beam 205 can be directed to the detection pupil relay optics 212 by the imaging optics 208. The detection pupil relay optics 212 can be disposed within the detection light beam 205 and include a first lens 214 and a second lens 216. It should be noted that FIG. 3 is just an exemplary embodiment, and the detection pupil relay optics 212 can include any number of lenses according to designs. The detection pupil relay optics 212 can be configured to form a detection pupil plane 218 in cooperation with collection optics 220. The collection optics 220 can be disposed within the detection light beam 205, and configured to direct the detection light beam 205 to a detector 222. The detector 222 is configured to receive the detection light beam 205 and acquire images of the sample 206.

In some embodiments, the first light modulator (not shown) can be substantially positioned in the detection pupil plane 218 to filter out signals from the detection light beam 205, where the signals originate from the uniform periodicity of the uniformly repeating structures on the sample 206.

In some embodiments, the spectroscopic microscope 200 can further include a second light source configured to generate a second incident light beam to illuminate the sample 206 on the stage. A beam splitter (e.g., 110) can be disposed within the detection light beam 205 and configured to direct the second incident light beam at a substantially vertical angle of incidence upon the sample 206. Thus, a dual illumination mode that includes both the dark filed illumination and the bright filed illumination can be introduced in the spectroscopic microscope 200.

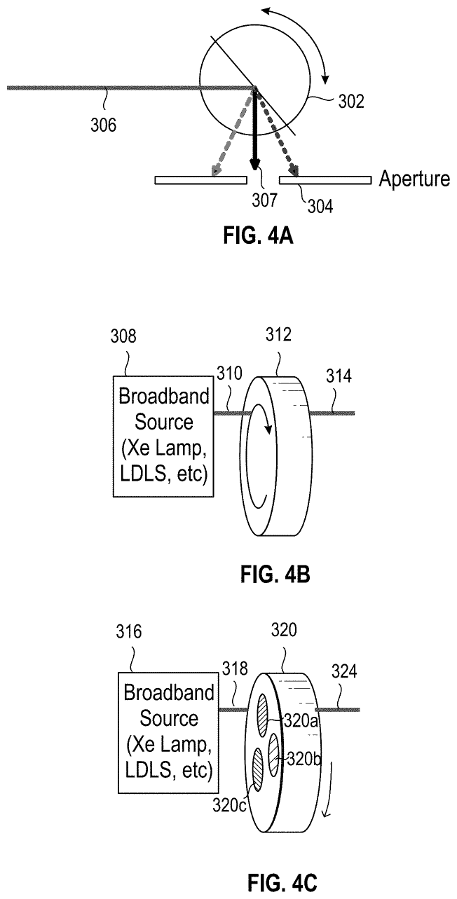

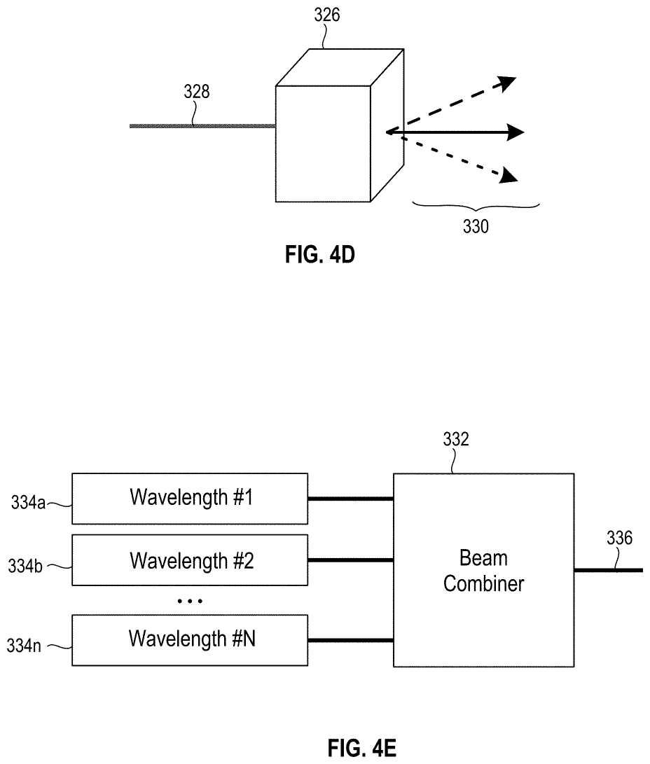

In the disclosure, the light source (e.g., 102 or 202) can apply an acousto-optical filter, a mechanical scanning with rotating diffraction grating or wavelength filters, or another methods to rapidly scan in time over wavelengths of interest. FIGS. 4A-4E illustrate various exemplary monochromators/wavelength filters that can be combined with the light source. For example, FIG. 4A shows a rotating stage 302 with diffraction grating that is coupled to an incident light beam 306. The incident light beam 306 can be filtered by the rotating stage 302 to generate illumination light beam 307 with wavelengths of interest. The illumination light beam 307 can further be directed through an aperture 304. FIG. 4B shows a rotating spectral filter 312 with variable spectral transmission that is coupled to an incident light beam 310 generated by a light source 308. The incident light beam 310 can be filtered by rotating spectral filter 312 to generate an illumination light beam 314 with different wavelengths in wavelength sweeps during an operation of the spectroscopic microscope 100 or 200. FIG. 4C shows a rotating spectral filter 320 with discrete number of small wavelength-specific filters 320a-320c. The rotating spectral filter 320 can be coupled to an incident light beam 318 generated by a light source 316 and generate an illumination light beam 324 with wavelengths of interest.

FIG. 4D shows an acousto-optical modulator 326 that can include a piezoelectric transducer which creates sound waves in a material like glass or quartz. An incident light beam 328 can be coupled to the acousto-optical modulator 326 and diffracted into an illumination beam 330 with several diffraction orders. FIG. 4E is a multi-source beam combiner 332 that can combine a plurality incident light beams 334a-334n with different wavelengths into an illumination light beam 336.

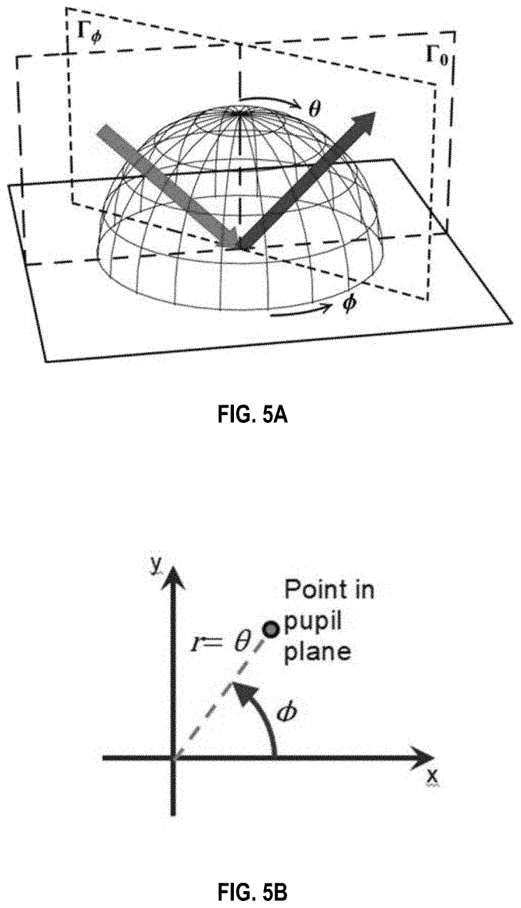

In the disclosure, optical collection subsystem of the system (e.g., 100 or 200) collects rays (or light) that are either reflected or scattered by a sample over a range of spatial/body angles. For a non-transparent surface, reflected/scattered rays are distributed over a scattering hemisphere, and are identified by two angles: azimuth (or Az, angle between ray projection into sample plane and in-plane coordinate axis) and AoS (or angle-of-scatter, angle between ray and coordinate axis, normal to the plane), that can be shown in FIGS. 5A and 5B. FIG. 5A shows a scattering hemisphere, where Γ₀ is a incidence plane, θ denotes angle-of-scattering (AoS), Γ_{ϕ} is a scattering plane, and ϕ is the azimuth (Az). FIG. 5B shows a pupil plane, where coordinates (r, ϕ) in the pupil plane correspond to (AoS, Az).

Still referring to FIG. 5B, optical collection path may include an intermediate pupil plane. In the pupil plane Az and AoS angular coordinates can turn into spatial XY coordinate system, which can also be represented by polar coordinate system r (or AoS) and ϕ (or Az). In the pupil plane a subsystem can be placed to control polarization of light (Pol) that reaches a sensor (e.g., 222). Also, the pupil plane may contain a mask of variable attenuation so that rays at undesired AoS & Az are either attenuated or blocked. For a bright field system, processing of light in the collection path pupil plane may be replaced with similar processing in an illumination path. In that case, AoS would be called AOI (angle-of-incidence).

In the form of equation, light attenuation in the pupil plane (not including polarization alterations) can be described by equation (1):

Eout(AoS,Az,WL,Pol)=T(AoS,Az,WL(t),Pol)*Ein(AoS,Az,WL,Pol) Eq. (1)

Where Ein and Eout are respectively input and output electric fields, and wavelength WL is a function of time. The approach mentioned above is different from hyperspectral cameras that sacrifice optical resolution for enhanced spectral sensitivity, and is also different from microscopes that provide “color” images with limited (typically <4) different wavelengths.

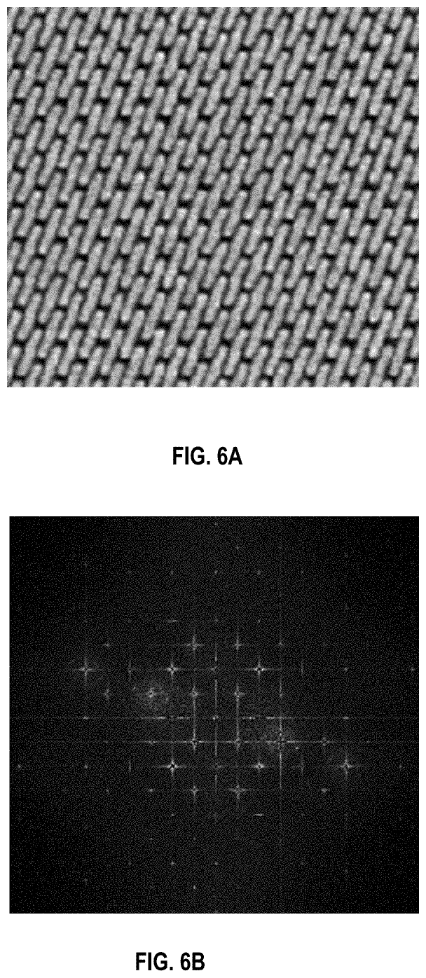

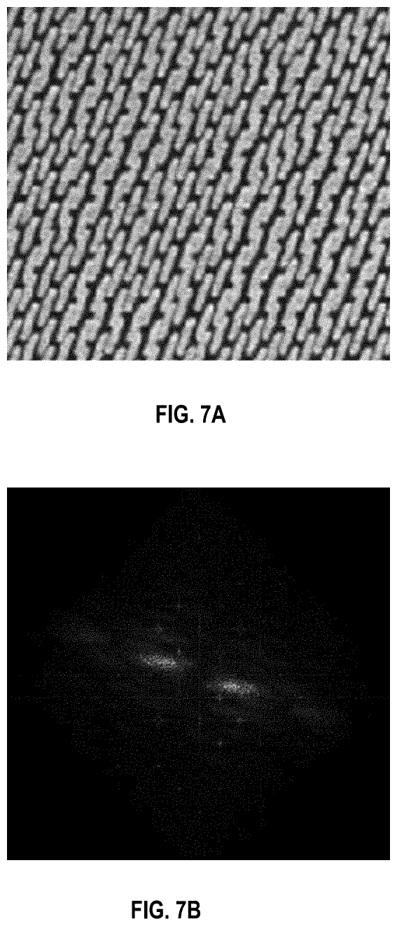

In an exemplary embodiment, the review station (e.g., 100 or 200) can have a programmable transmission or reflection-based pupil plane modulator/spatially resolving attenuation filter that can be positioned at the pupil plane (e.g., 122 or 218). The primary purpose of such spatial light modulator (SLM) is to filter out periodic structure signal based on a pre-calculated or pre-measured distribution of the periodic structure signal in the pupil plane, and transmit distribution from the defects in the sample. FIG. 6A is a first image of a periodic structure obtained by CD-SEM from a sample (or a semiconductor sample), where the periodic structure has no defects. FIG. 6B is a first corresponding pupil plane distribution after filtering out the periodic structure of the sample. FIG. 7A is a second image of a periodic structure with multiple defects obtained by CD-SEM from a semiconductor sample. FIG. 7B is a second corresponding pupil plane distribution after filtering out the periodic structure in the sample. As shown in FIG. 7B, signals from the multiple defects can be caught by filtering out signals from the periodic structure in the sample.

Various methods can be applied to form the actual spatial light modulation (SLM). For example, the SLM can be made of (a) a mechanical system that includes multiple adjustable wires, (b) a multi-pixel liquid crystal panel with control over transmission/polarization of individual pixels (LC-SLM), (c) a MEMS structure of individually controlled transmission blocking “flaps”, wires, or deformable mirrors, and (d) a controlled acousto-optical deflection (AOD).

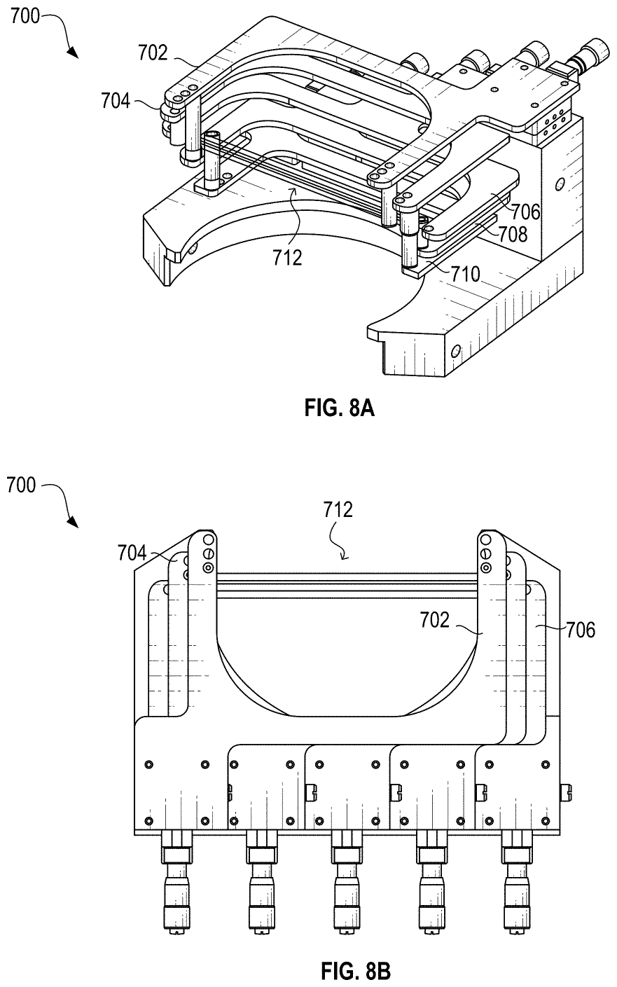

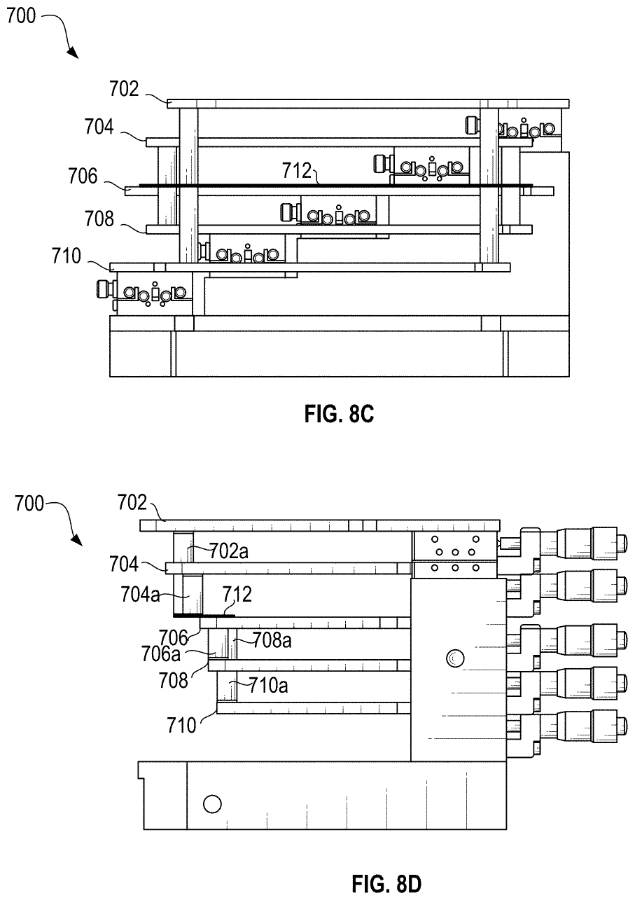

FIGS. 8A-8D shows a mechanical spatial light modulator (SLM) 700 that can be positioned in a pupil plane (e.g., 122 or 218) to filter out the periodic structure of the sample. FIG. 8A is a 3D schematic view of the mechanical SLM 700. FIG. 8B is a top down view of the mechanical SLM 700. FIG. 8C is a front view of the mechanical SLM 700. FIG. 8D is a side view of the mechanical SLM 700. As shown in FIGS. 8A-8D, the mechanical SLM 700 can include a plurality of wires 712, such as five wires. Each of the wires 712 can be mounted on a respective “fork” structure (e.g., 702-710). Each of the fork structures 702-710 can be individually adjustable with a manual or motorized micrometer. Each of the fork structures 702-710 can be positioned in a different plane along a path of beam propagation, such as the detection light beam 109 or 205. Further, wires 712 can be attached to posts 702a-710a of varying length so that all wires are arranged in a same plane (or pupil plane).

In the disclosure, the wire positions can be adjusted using a calibration procedure, designed to minimize signal from the periodic structure. The calibration procedure can include one of or a combination of three approaches: (a) theoretical calculation of locations of periodic grating intensity peaks in a pupil plane; (b) taking an image of the pupil plane with a camera. In one embodiment the camera with imaging lens may be positioned on a fixture, which also includes a mirror that flips in and out of a main optical path, or a permanently positioned beam splitter; and (c) minimizing signal from a reference sample. The reference sample can contain a same periodic structure as a target sample, but be substantially free from defects.

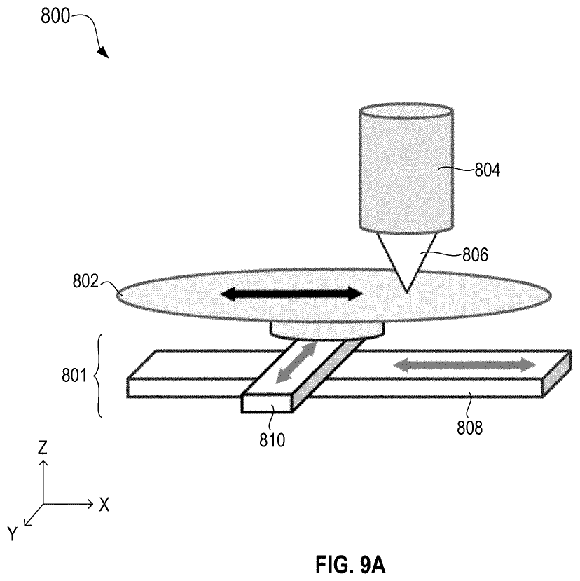

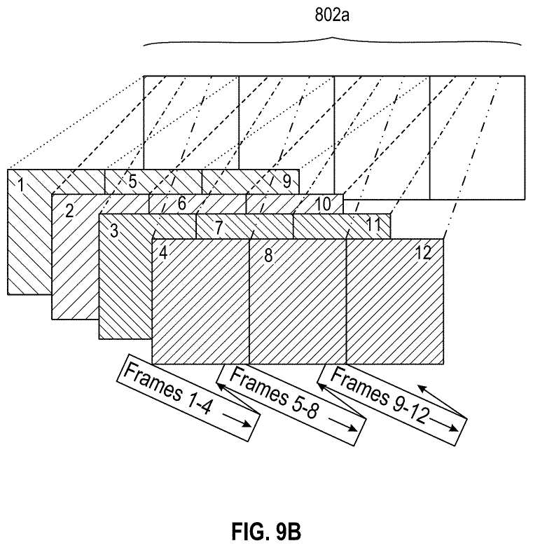

FIG. 9A is a schematic view of a scanning spectroscopic microscope (or a system or a review station) 800 in accordance with some embodiments. As shown in FIG. 9A, the scanning spectroscopic microscope 800 can include a wafer stage (or stage) 801 and a detection portion 804. The detection portion 804 can have similar configurations to the spectroscopic microscope 100 or 200, where the detection portion 804 can generate an incident light beam 806. The incident light beam 806 can be directed to a sample wafer 802 and scattered or reflected by the sample wafer 802. The scanning spectroscopic microscope 800 thus can collect light scattered from the sample wafer and form images through a sensor (e.g., 126 or 222) for a region of the sample wafer 802, where the region can have one dimension of at least 100 mm. The wafer stage 801 can include a first translation track 808 along a X direction and a second translation track 810 along a Y direction. The wafer stage 801 can be commanded to move while the images are being collected so that the sample wafer 802 is moved by a fixed distance D between sequential frames of the images, where D×N=frame field-of-view size (FOV), and N is the number of different illumination modes. In a cycle of inspection, a first frame of the images can be captured by the scanning spectroscopic microscope 800 under a first illumination mode (e.g., a first wavelength, or a first polarization). The cycle can then proceed to capture a next frame under a second illumination mode (e.g., a second wavelength, or a second polarization). The cycle can repeat after N frames, and in each of the cycles the wafer stage 801 can translate by a distance equal to FOV.

In the disclosure, the system (e.g., 100, 200, or 800) can substantially use a “flood” approach, where full field-of-view on a sample can be illuminated, and imaged on all pixels of a sensor at a same time. This is in contrast to spot-scanning or line-scanning systems typical for some existing semiconductor wafer inspection systems. By implementing the “flood” approach, a sample can further be allowed to move with respect to the system. Further, by simultaneously changing the wavelength, the system can record multiple images of a same area on the sample with different wavelengths, and then “sew” or “stitch” the multiple images of the same area together, which can be shown in FIG. 9B. Alternatively, in another embodiment, the system may operate in a point-to-point mode, where the point-to-point mode can focus on a first area of a sample, scan through multiple wavelengths, and then move to a second area of the sample. Alternatively, in another embodiment, the system may use sequential scans of the whole wafer, each scan at specific wavelength and SLM settings.

FIG. 9B illustrates a schematic view of sequential frame acquisition with multiple illumination modes operated by the system. In the disclosure, the system (e.g., 100, or 200, or 800) can be a point-to-point review station so that a plurality of areas (or regions) of the sample are inspected sequentially, and each of the areas can be inspected through multiple illumination wavelengths, or multiple polarizations. As shown in FIG. 9B, the system can inspect a region 802a of the sample wafer 802, where frames can be collected at equidistant time intervals. In an exemplary embodiment of FIG. 9B, four illumination modes can be applied. Thus, frame 1 can be collected at a time interval ‘t’ with a first illumination mode (e.g., a wavelength of “violet”). Frame 2 can be collected at a time interval ‘t+A’ with a second illumination mode (e.g., a wavelength of “green”). Frame 3 can be collected at a time interval ‘t+2Δ’ with a third illumination mode (e.g., a wavelength of “yellow”), and frame 4 can be collected at a time interval ‘t+3Δ’ with a fourth illumination mode (e.g., a wavelength of “red”). Frames 5-8 can repeat such a cycle, with frame 5 being collected at a time interval ‘t+4Δ’ with the wavelength of “violet” and so on. When the whole acquisition is completed, “violet” frames 1, 5, and 9 can be stitched together to form a first continuous coverage of the region 802a under the first illumination mode, same goes for other frames under other illumination modes. For example, “green” frames 2, 6, and 10 can form a second continuous coverage of the region 802a under the second illumination mode.

In the disclosure, the system is a process-integrated sensitivity-based optical review system that is optimized for detecting the types of defects on periodic structures, which result in the change of the effective pitch of the periodic structures. One example is a zip line-like pattern collapse defect, which can double the effective pitch of a 2D-structure in one direction.

Existing CD-SEM systems use the method of resolving actual defects. Therefore the existing CD-SEM systems suffer from limited field-of-view and are inferior in terms of wafer throughput. In order to measure a meaningful portion of a wafer and establish defect statistics, CD-SEM system may need to spend hours reviewing a single wafer.

Existing scanning microscope-based optical inspection solutions do not provide a capability to perform sequential measurements with multiple channels, and therefore are inferior in terms of the amount of information they provide.

Existing spectroscopic ellipsometers and reflectometers have spot size that is too large to achieve useful SNR with a single defect. Furthermore, the existing spectroscopic ellipsometers and reflectometers measure specular reflection and changes in signal from a period pattern in a bright field. Such systems are further limited in defect signal may only be marginally different from background structure signal.

By rapidly scanning over wavelengths, the disclosed system provides spectroscopic information for individual sub-micron sized pixels, coupled with ability to filter out signal from a periodic pattern with a programmable Fourier plane filter.

Obviously, numerous modifications and variations are possible in light of the above teachings. It is therefore to be understood that within the scope of the appended claims, the invention may be practiced otherwise than as specifically described herein. Thus, the foregoing discussion discloses and describes merely exemplary embodiments of the present invention. As will be understood by those skilled in the art, the present invention may be embodied in other specific forms without departing from the spirit or essential characteristics thereof. Accordingly, the disclosure of the present invention is intended to be illustrative, but not limiting of the scope of the invention, as well as other claims. The disclosure, including any readily discernible variants of the teachings herein, defines, in part, the scope of the foregoing claim terminology such that no inventive subject matter is dedicated to the public.

What is claimed is:

1. A defect inspection apparatus for detecting defects on a sample, the sample comprising a uniformly repeating structure, the defects comprising deviations from uniform periodicity of the uniformly repeating structure, comprising:
a stage for receiving the sample to be inspected;
a first light source configured to generate an incident light beam to illuminate the sample on the stage, the first light source configured to sequentially emit light of different wavelengths in wavelength sweeps;
imaging optics for collecting light scattered from the sample and for forming a detection light beam;
a detector for receiving the detection light beam and acquiring images of the sample;
collection optics disposed within the detection light beam, and configured to direct the detection light beam to the detector; and
a first light modulator, the first light modulator configured to filter out signals from the detection light beam, the signals originating from the uniform periodicity of the uniformly repeating structures on the sample, wherein the defect inspection apparatus is configured for imaging a region of the sample, the region having one dimension of at least 100 μm.

2. The defect inspection apparatus of claim 1, wherein the first light modulator comprises at least one of a monochromator, a polarizer, a filter, a mask, a spatial light modulator (SLM) including a mechanical SLM, a multi-pixel liquid crystal panel with controlled transmission, a MEMS structure with controlled transmission, or a controlled acousto-optical deflection structure.

3. The defect inspection apparatus of claim 2, wherein the mechanical SLM comprises wires and fork structures, wherein:
each of the wires is mounted on a respective fork structure of the fork structures,
each of the fork structures is positioned in a respective plane perpendicular to the detection light beam,
each of the fork structures is adjustable with a manual or motorized micrometer, and
the wires are positioned in a same plane that is perpendicular to the detection light beam and configured to block the signals originating from the uniform periodicity of the uniformly repeating structures on the sample.

4. The defect inspection apparatus of claim 1, further comprising:
detection pupil relay optics disposed within the detection light beam and configured to form a detection pupil plane in cooperation with the collection optics,
wherein the first light modulator is located substantially in the detection pupil plane.

5. The defect inspection apparatus of claim 1, further comprising:
a beam splitter disposed within the detection light beam and configured to direct the incident light beam at a substantially vertical angle of incidence upon the sample.

6. The defect inspection apparatus of claim 5, further comprising:
illumination pupil relay optics disposed within the incident light beam and configured to form an illumination pupil plane in cooperation with the first light source,
wherein the first light modulator is located substantially in the illumination pupil plane.

7. The defect inspection apparatus of claim 1, wherein the first light source is configured to illuminate the sample at an incidence angle from 5 degrees to 90 degrees.

8. The defect inspection apparatus of claim 7, further comprising:
a specular reflection analyzer for detecting and analyzing spatial and spectral properties of specularly reflected light from the sample.

9. The defect inspection apparatus of claim 1, further comprising:
a monochromator coupled to the first light source and positioned between the first light source and the sample, the monochromator being configured to adjust the wavelengths of the incident light beam.

10. The defect inspection apparatus of claim 7, further comprising:
a second light source configured to generate a second incident light beam to illuminate the sample on the stage; and
a beam splitter disposed within the detection light beam and configured to direct the second incident light beam at a substantially vertical angle of incidence upon the sample.

11. The defect inspection apparatus of claim 1, wherein the first light source comprises at least one of a rotating stage with diffraction grating, a rotating spectral filter, acousto-optical modulator, or a multi-source beam combiner so that the first light source sequentially emits the light of different wavelengths in the wavelength sweeps during an operation of the defect inspection apparatus.

12. The defect inspection apparatus of claim 1, wherein the stage is a point-to-point stage so that a plurality of areas of the sample are inspected sequentially, each of the areas being inspected through multiple illumination wavelengths, or multiple polarizations.

13. The defect inspection apparatus of claim 1, wherein the detector comprises at least one of a two-dimensional (2D) imaging multi-pixel sensor, a one-dimensional (1D) line sensor, a time-delayed integration sensor, a single-pixel position-sensitive sensor, a photomultiplier tube, or a photodiode.

14. A defect inspection apparatus for detecting defects on a sample, the sample comprising a uniformly repeating structure, the defects comprising deviations from uniform periodicity of the uniformly repeating structure, comprising:
a stage for receiving a sample to be inspected;
a light source configured to generate an incident light beam to illuminate the sample on the stage, the light source configured to sequentially emit light of different wavelengths in wavelength sweeps;
imaging optics for collecting light scattered from the sample and for forming a detection light beam;
a detector for receiving the detection light beam and acquiring images of the sample;
collection optics disposed within the detection light beam, and configured to direct the detection light beam to the detector; and
a mechanical spatial light modulator (SLM) configured to filter out signals from the detection light beam, the signals originating from the uniform periodicity of the uniformly repeating structures on the sample, wherein the defect inspection apparatus and detector are configured for imaging a region of a sample, the region having one dimension of at least 100 μm.

15. The defect inspection apparatus of claim 14, further comprising:
detection pupil relay optics disposed within the detection light beam and configured to form a detection pupil plane in cooperation with the collection optics,
wherein the mechanical SLM is located substantially in the detection pupil plane.

16. The defect inspection apparatus of claim 15, wherein the mechanical SLM comprises wires and fork structures, wherein:
each of the wires is mounted on a respective fork structure of the fork structures,
each of the fork structures is positioned in a respective plane perpendicular to the detection light beam,
each of the fork structures is adjustable with a manual or motorized micrometer, and
the wires are positioned in a same plane that is perpendicular to the detection light beam and configured to block the signals originating from the uniform periodicity of the uniformly repeating structures on the sample.

17. The defect inspection apparatus of claim 14, further comprising:
a beam splitter disposed within the detection light beam and configured to direct the incident light beam at a substantially vertical angle of incidence upon the sample;
illumination pupil relay optics disposed within the incident light beam and configured to form an illumination pupil plane in cooperation with the light source; and
a light modulator that is located substantially in the illumination pupil plane, the light modulator including at least one of a monochromator, a polarizer, a filter, or a mask.

18. The defect inspection apparatus of claim 14, further comprising:
a specular reflection analyzer for detecting and analyzing spatial and spectral properties of specularly reflected light from the sample; and
a monochromator coupled to the light source and positioned between the light source and the sample, the monochromator being configured to adjust wavelengths of the incident light beam, wherein:
the light source is configured to illuminate the sample at an incidence angle from 5 degrees to 90 degrees.

19. The defect inspection apparatus of claim 14, wherein the stage is a point-to-point stage so that a plurality of areas of the sample are inspected sequentially, each of the areas being inspected through multiple illumination wavelengths, or multiple polarizations.

20. A wafer cleaning system, comprising:
a wafer cleaning module;
a wafer drying module;
a defect inspection module configured to detect defects on a wafer that is received from the wafer drying module, the wafer including a portion that includes a uniformly repeating structure; and
a wafer transfer module configured to transfer the wafer between the wafer cleaning module, the wafer drying module, and the defect inspection module,
wherein the defect inspection module comprises:
a stage for receiving the wafer to be inspected;
a light source configured to generate an incident light beam to illuminate the portion of the wafer on the stage, the light source configured to sequentially emit light of different wavelengths in wavelength sweeps;
imaging optics for collecting light scattered from the portion of the wafer, and for forming a detection light beam;
a detector for receiving the detection light beam and acquiring images of the portion of the wafer;
collection optics disposed within the detection light beam, and configured to direct the detection light beam to the detector; and
a first light modulator, the first light modulator configured to filter out signals from the detection light beam, the signals originating from uniform periodicity of the uniformly repeating structures on the portion of the wafer, wherein the defect inspection module is configured for imaging a region of the portion of the wafer, the region having one dimension of at least 100 μm.
